(19) United States
(12) Patent Application Publication
(10) Pub. No.: US 2012/0074531 A1
(43) Pub. Date: Mar. 29, 2012

(54) EPITAXY SUBSTRATE

(75) Inventors: PO-MIN TU, Hukou (TW); SHIH-CHENG HUANG, Hukou (TW); CHIA-HUNG HUANG, Hukou (TW); SHUN-KUEI YANG, Hukou (TW)

(73) Assignee: ADVANCED OPTOELECTRONIC TECHNOLOGY, INC., Hsinchu Hsien (TW)

(21) Appl. No.: 13/151,254

(22) Filed: Jun. 1, 2011

(30) Foreign Application Priority Data
Sep. 23, 2010 (CN) 201010289813.9

(51) Int. Cl. H01L 29/02

(52) U.S. Cl. 257/622; 257/E29.002

(57) ABSTRACT

An epitaxy substrate for growing a plurality of semiconductor epitaxial layers thereon, includes a plurality of growth areas and a plurality of protected areas. The growth areas are provided for growing the semiconductor epitaxial layers thereon. The growth areas and the protected areas are alternating. A thickness of the growth areas is less than ⅓ of a thickness H of the protected areas.

### BACKGROUND

1. Technical Field

The present disclosure generally relates to epitaxy substrates and, more particularly, to an epitaxy substrate for growing a light emitting diode (LED) with high lattice quality.

2. Discussion of Related Art

LEDs have many advantages, such as high luminosity, low operational voltage, low power consumption, compatibility with integrated circuits, easy driving, long term reliability, and environmental friendliness which have promoted the wide use of LEDs as a lighting source.

Generally, LEDs are formed by growing semiconductor epitaxial layer on an epitaxy substrate. However, the lattice mismatch between the lattice coefficient of the substrate and that of the semiconductor epitaxial layer is greater than 13%. Such lattice mismatch can degrade the quality of the semiconductor epitaxial layer grown on the epitaxy substrate, and the stress resulting from the lattice mismatch further brings about layer defects, including layer cracking.

Therefore, what is needed is an epitaxy substrate which can overcome the described limitations.

### BRIEF DESCRIPTION OF THE DRAWINGS

FIG. 1 is a cross-sectional view of an epitaxy substrate, in accordance with a first embodiment of the present disclosure, with semiconductor epitaxial layer and protecting layer formed thereon.

FIG. 2 is similar to FIG. 1, but shows a cross-sectional view of an epitaxy substrate, in accordance with a second embodiment of the present disclosure.

### DETAILED DESCRIPTION OF EMBODIMENTS

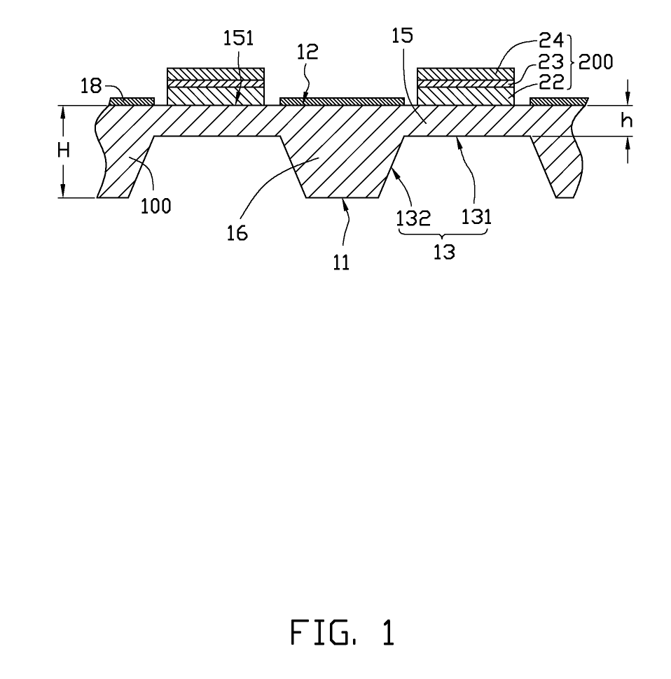

Referring to FIG. 1, an epitaxy substrate 100, in accordance with a first embodiment, is provided. The epitaxy substrate 100 includes a plurality of growth areas 15 and a plurality of protected areas 16. The growth areas 15 and protected areas 16 are alternating. The epitaxy substrate 100 includes a first surface 11 and a second surface 12 opposite to the first surface 11. In the present embodiment, the second surface 12 is planar. The epitaxy substrate 100 can be made of Si or SiC.

Portions of the first surface 11 of the epitaxy substrate 100 aligning with the growth areas 15 each defines a groove 13 recessed upwards. The substrate 100 forms a bottom surface 131 at a top side of the groove 13 and a side surface 132 enclosing the groove 13 and adjoining the bottom surface 131. The bottom surface 131 of the groove 13 is planar, and the side surface 132 is slanted downwardly and outwardly from the bottom surface 131. The bottom surface 131 and each side surface 132 cooperatively form an inclined obtuse angle; in other words, a size (i.e., width) of the groove 13 is gradually decreased along a direction away from the first surface 11 towards the second surface 12. Other portions of the first surface 11 corresponding to the protected areas 16 each are planar, and are lower than the bottom surfaces 131.

A portion of the second surface 12 of the epitaxy substrate 100 aligning with each of the growth areas 15 is regarded as a growth surface 151. The distance between the bottom surfaces 131 and the growth surfaces 151 is the thickness h of the growth area 15. The distance between the other portion of the first surface 11 corresponding to each of the protected areas 16 and the second surface 12 is the thickness H of the protected areas 16. The thickness H of the protected areas 16 and the thickness h of the growth area 15 satisfy a condition: h/H<⅓. Generally, the thickness H of the protected areas 16 ranges from 250 microns to 450 microns, and the thickness h of the growth areas 15 ranges from 10 microns to 133 microns.

A protected layer 18 is formed on each of portions of the second surface 12 respectively aligning with the protected areas 16. The protected layer 18 can be of SiO₂ or SiNx. In the present embodiment, the protected layer 18 encircles each of the growth surfaces 151, and thus the growth surfaces 151 are discontinuous.

The growth surfaces 151 are used for growing semiconductor epitaxial layers 200, each generally including a first semiconductor layer 22, an active layer 23, and a second semiconductor layer 24 grown on one corresponding growth surface 151 of the epitaxy substrate 100 in sequence. Since the growth areas 15 are thinner than the protected areas 16, the thermal stress due to the lattice mismatch between the lattice coefficients of the growth areas 15 and the semiconductor epitaxial layers 200 during growth of the semiconductor epitaxial layer 200 and cooling of the epitaxy substrate 100 and the semiconductor epitaxial layer 200 can be reduced. Furthermore, since the growth surfaces 151 are discontinuous, the semiconductor epitaxial layers 200 formed on the growth surfaces 151 are discontinuous too. The isolation of the semiconductor epitaxial layers 200 from each other also reduces the thermal stress in the semiconductor epitaxial layers 200.

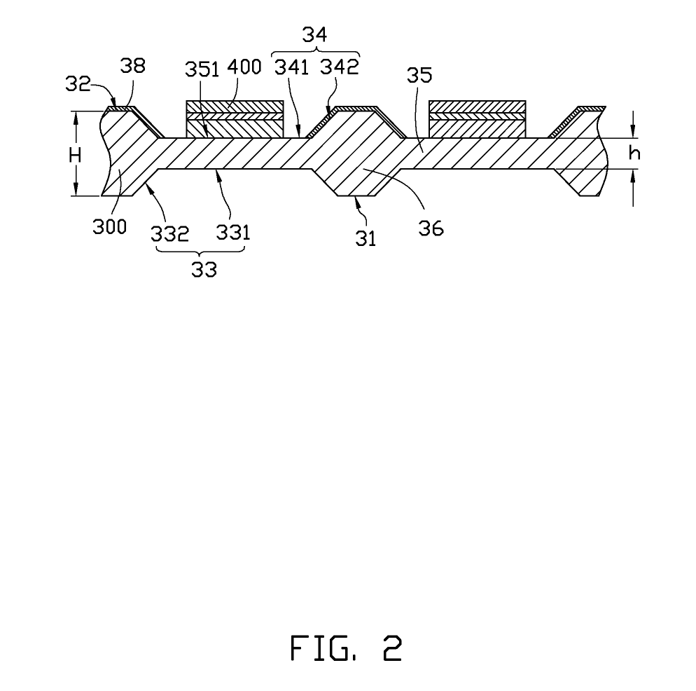

Referring to FIG. 2, an epitaxy substrate 300 according to a second embodiment is shown. The epitaxy substrate 300 includes a plurality of growth areas 35 and a plurality of protected areas 36 arranged alternating. Differing from the epitaxy substrate 100 of the first embodiment, not only portions of the first surface 31 of the epitaxy substrate 300 aligning with the growth areas 35 define a plurality of first grooves 33 recessed upwards, but also portions of the second surface 32 of the epitaxy substrate 300 aligning with the growth areas 35 correspondingly define a plurality of second grooves 34 recessed downwards.

The epitaxy substrate 300 forms a first bottom surface 331 at a top side of the groove 31 and a first side surface 332 enclosing the groove 31 and adjoining to the bottom surface 331. The first bottom surface 331 of the first groove 33 is planar, and the first side surface 332 is slanted downwardly and outwardly. The first bottom surface 331 and the first side surface 332 cooperatively form an inclined obtuse angle; in other words, a width of the first groove 33 is gradually decreased along a direction away from the first surface 31 towards the second surface 12. Other portions of the first surface 31 corresponding to the protected areas 36 are planar and lower than the bottom surfaces 331.

The substrate 300 forms a second bottom surface 341 at a bottom side of the groove 34 and a second side surface 342 enclosing the groove 34 and adjoining to the second bottom surface 341. In the present embodiment, a shape and depth of the second groove 34 are the same as those of the first groove 33. In other words, the first and second grooves 33, 34 are mirror-imaged to each other about a horizontal central line (not shown) of the substrate 300. The second bottom surface 341 of the second groove 34 is regarded as a growth surface 351 for growing a semiconductor epitaxial layer 400.

The distance between the first surface 31 and the second surface 32 corresponding to the protected areas 36 is as the thickness H of the protected areas 36. The distance between the first bottom surface 331 of the first groove 33 and the second bottom surface 341 of the second groove 34 is as the thickness h of the growth areas 35. The thickness H of the protected areas 36 and the thickness h of the growth areas 35 satisfy a condition: h/H<⅓. Generally, the thickness H of the protected areas 36 ranges from 250 microns to 450 microns, and the thickness h of the growth areas 35 ranges from 10 microns to 133 microns.

The protected layer 38 is formed on the second side surface 342 of the second groove 34 and the portions of the second surface 32 aligning with the protected areas 36. In the present embodiment, the protected layer 38 can be made of SiO₂ or SiNx. The protected layers 38 encircle the semiconductor epitaxial layers 400, and the semiconductor epitaxial layers 200 are discontiguous from each other.

It is to be further understood that even though numerous characteristics and advantages have been set forth in the foregoing description of embodiments, together with details of the structures and functions of the embodiments, the disclosure is illustrative only; and that changes may be made in detail, especially in matters of shape, size, and arrangement of parts within the principles of the disclosure to the full extent indicated by the broad general meaning of the terms in which the appended claims are expressed.

What is claimed is:

1. An epitaxy substrate for growing a plurality of semiconductor epitaxial layers, comprising a plurality of growth areas and a plurality of protected areas, the growth areas being adapted for growing the semiconductor epitaxial layers thereon, the growth areas and the protected areas being alternating, a thickness of the growth areas being less than ⅓ of a thickness of the protected areas.

2. The epitaxy substrate of claim 1, wherein the epitaxy substrate comprises a first surface and an opposite second surface adapted for growing the semiconductor epitaxial layers thereon, the first surface defining a plurality of first grooves corresponding to the growth areas.

3. The epitaxy substrate of claim 2, further comprising a protected layer formed on each of portions of the second surface aligning with the protected areas.

4. The epitaxy substrate of claim 3, wherein the protected layer is made of SiO₂ or SiNx.

5. The epitaxy substrate of claim 2, wherein each first groove converges inwards from the first surface towards the second surface.

6. The epitaxy substrate of claim 2, wherein the second surface is planar.

7. The epitaxy substrate of claim 2, wherein the second surface defines a plurality of second grooves corresponding to the growth areas, and the epitaxy substrate forms a growth face at a bottom of each of the second grooves for growing a corresponding semiconductor epitaxial layer thereon.

8. The epitaxy substrate of claim 7, wherein the second grooves converge inwards from the second surface towards the first surface, a side surface surrounding each second groove forming an inclined obtuse angle with respect to a corresponding growth face.

9. The epitaxy substrate of claim 8, further comprising protected layers formed on the side surfaces and the second surface.

10. The epitaxy substrate of claim 9, wherein the protected layer is made of SiO₂ or SiNx.

11. The epitaxy substrate of claim 9, wherein the thickness of the protected areas ranges from 250 microns to 450 microns, and the thickness of the growth areas ranges from 10 microns to 133 microns.

12. An epitaxy substrate for growing semiconductor epitaxial layers, comprising:
a plurality of growth areas and a plurality of protected areas being alternating; the epitaxy substrate comprising a first surface and a second surface opposite to the first surface; portions of the first surface aligning with the growth areas defining a plurality of first grooves; portions of the second surface aligning with the growth areas being adapted for growing the semiconductor epitaxial layers thereon; a thickness h of the protected areas and a thickness H of the protected areas being satisfied a condition: h/H<⅓.

13. The epitaxy substrate of claim 12, wherein each first groove converges inwards from the first surface towards the second surface.

14. The epitaxy substrate of claim 12, wherein the portions of the second surface corresponding to the growth areas are recessed inwards to define a plurality of second grooves, a growth surface is formed at a bottom of each second groove for growing a corresponding semiconductor epitaxial layer thereon, a side surface enclosing each second groove, the side surface and the growth surface cooperatively forming an inclined obtuse angle therebetween.

15. The epitaxy substrate of claim 14, wherein the first grooves are the same as the second grooves.

16. The epitaxy substrate of claim 14, further comprising a protected layer formed on the side surface and the second surface.

17. The epitaxy substrate of claim 16, wherein the protected layer is made of SiO₂ or SiNx.
